(19) United States
(12) Patent Application Publication
(10) Pub. No.: US 2017/0294354 A1
(43) Pub. Date: Oct. 12, 2017

(54) INTEGRATION OF NOMINAL GATE WIDTH FINFETS AND DEVICES HAVING LARGER GATE WIDTH

(71) Applicant: GLOBALFOUNDRIES Inc., Grand Cayman (KY)

(72) Inventor: Shivaji PEDDETI, Ballston Lake, NY (US)

(73) Assignee: GLOBALFOUNDRIES Inc., Grand Cayman (KY)

(21) Appl. No.: 15/093,272

(22) Filed: Apr. 7, 2016

(51) Int. Cl. H01L 21/8234; H01L 21/027; H01L 21/033; H01L 27/088

(52) U.S. Cl. CPC H01L 21/823431; H01L 27/0886; H01L 21/0276; H01L 21/0332

(57) ABSTRACT

A starting semiconductor structure includes a layer of filler material (e.g., amorphous silicon), a hard mask layer over the layer of filler material, and filler material lines over the hard mask layer. A protective layer is formed over one or more, but less than all of the filler material lines, at least one protected filler material line and at least one unprotected filler material line have a same width, and, after forming the protective layer, oxidizing unprotected filler material lines, such that the oxidized unprotected line(s) have a larger width than the protected filler material line(s).

### BACKGROUND OF THE INVENTION

### Technical Field

The present invention generally relates to FinFET fabrication using a replacement metal gate process. More particularly, the present invention relates to co-fabrication of FinFETs with nominal gate width and FinFETs with wider than nominal gate widths.

### Background Information

In order to continue reducing the size of semiconductor devices (transistors), self-aligned double and quadruple patterning processes have been developed for replacement metal gate processes to increase dummy gate width. However, these processes use non-lean chemistry, which increases cost, suffer low etch rates lowering throughput, and/or increase defects reducing yield.

Thus, a need exists for a way to increase dummy gate width that does not increase costs, lower throughput or reduce yields.

### SUMMARY OF THE INVENTION

The shortcomings of the prior art are overcome and additional advantages are provided through the provision, in one aspect, of a method of integrating nominal gate width devices with larger than nominal gate width devices. The method includes providing a starting semiconductor structure, the starting semiconductor structure including a filler material layer, a hard mask layer over the filler material layer, and filler material lines over the hard mask layer. The method further includes forming a protective layer over one or more, but less than all of the filler material lines, at least one protected filler material line and at least one unprotected filler material line having a same width, and, after forming the protective layer, oxidizing unprotected filler material lines, the oxidized at least one unprotected filler material line having a larger width than the at least one protected filler material line.

In another aspect a semiconductor structure is provided. The semiconductor structure includes a FinFET in fabrication, the FinFET including a first filler material layer, a layer of silicon nitride over the first filler material layer and filler material lines over the layer of silicon nitride, and at least one of the filler material lines being surrounded by a layer of oxide.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional view of one example of a starting semiconductor structure, the starting semiconductor structure including a bulk semiconductor substrate, a first layer of filler material (e.g., amorphous silicon or polysilicon) above the semiconductor substrate, a hard mask layer (e.g., silicon nitride) over the first filler material layer, and multiple filler material lines over the hard mask layer, in accordance with one or more aspects of the present invention.

FIG. 2 depicts the starting semiconductor structure of FIG. 1 after forming a protective layer over one or more of the filler material lines, in accordance with one or more aspects of the present invention.

FIG. 3 depicts the structure of FIG. 2 after forming an oxide surrounding unprotected filler material lines, in accordance with one or more aspects of the present invention.

FIG. 4 depicts the structure of FIG. 3 after removal of the protective layer, formation of hard mask lines from the hard mask layer using the filler material lines as mandrels, and removal thereof, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

As used herein, unless otherwise specified, the term “about” used with a value, such as measurement, size, etc., means a possible variation of plus or minus five percent of the value. Also, unless otherwise specified, a given aspect of semiconductor fabrication described herein may be accomplished using conventional processes and techniques, where part of a method, and may include conventional materials appropriate for the circumstances, where a semiconductor structure is described.

As used herein, the term “nominal gate width” refers to a gate width of about 20 nm to about 24 nm when used for the 10 nm technology node, and a gate width of about 16 nm to about 20 nm when used for the 7 nm technology node. As used herein, the term “wider than nominal gate width” refers to a width difference as compared to nominal of about 2 nm to about 5 nm.

Reference is made below to the drawings, which are not drawn to scale for ease of understanding, wherein the same reference numbers are used throughout different figures to designate the same or similar components.

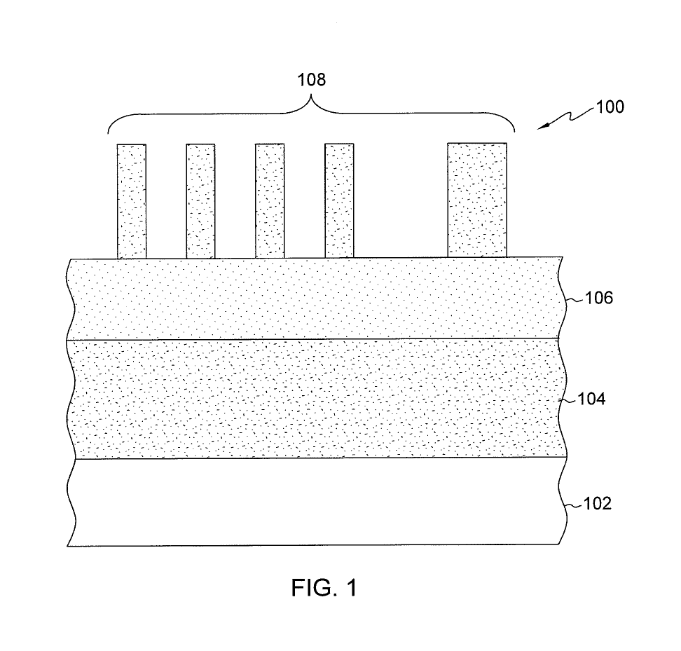

FIG. 1 is a cross-sectional view of one example of a starting semiconductor structure 100, the starting semiconductor structure including a bulk semiconductor substrate 102, a first filler material layer 104 (e.g., amorphous silicon or polysilicon) above the semiconductor substrate, a hard mask layer 106 (e.g., silicon nitride) over the first filler material layer, and multiple filler material lines 108 over the hard mask layer, in accordance with one or more aspects of the present invention.

The starting structure may be conventionally fabricated, for example, using known processes and techniques. Further, unless noted otherwise, conventional processes and techniques may be used to achieve individual steps of the fabrication process of the present invention. However, although only a portion is shown for simplicity, it will be understood that, in practice, many such structures may be included on the same bulk substrate.

In one example, substrate 102 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof

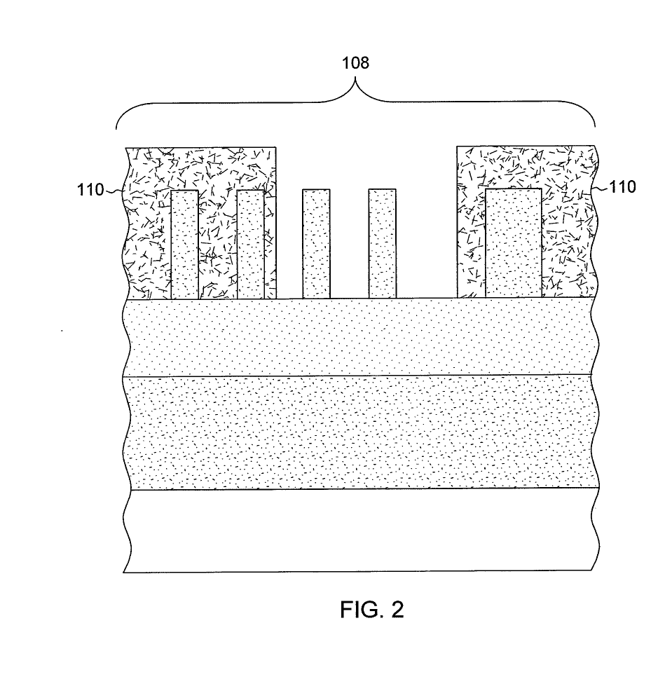

FIG. 2 depicts the starting semiconductor structure 100 of FIG. 1 after forming a protective layer 110 over one or more of the filler material lines 108, in accordance with one or more aspects of the present invention.

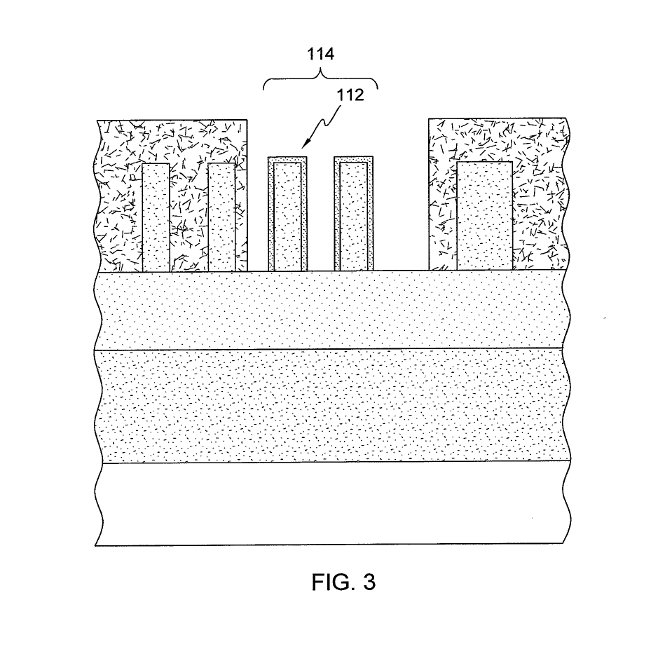

FIG. 3 depicts the structure of FIG. 2 after forming an oxide surrounding unprotected filler material lines, in accordance with one or more aspects of the present invention.

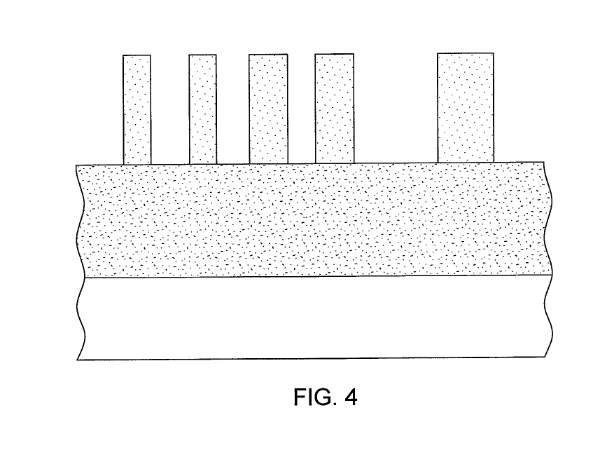

FIG. 4 depicts the structure of FIG. 3 after removal of the protective layer, formation of hard mask lines from the hard mask layer using the filler material lines as mandrels, and removal thereof, in accordance with one or more aspects of the present invention.

In a first aspect, disclosed above is a method. The method includes providing a starting semiconductor structure, the starting semiconductor structure including a filler material layer, a hard mask layer over the filler material layer, and filler material lines over the hard mask layer. The method further includes forming a protective layer over one or more, but less than all of the filler material lines, at least one protected filler material line and at least one unprotected filler material line having a same width, and, after forming the protective layer, oxidizing unprotected filler material lines. The oxidized at least one unprotected filler material line has a larger width than the at least one protected filler material line.

In one example, forming the protective layer may include, for example, forming a blanket protective layer over the starting semiconductor structure, and removing portion(s) of the blanket protective layer, exposing filler material lines to be unprotected. In one example, the blanket protective layer may include, for example, a bottom anti-reflective coating material.

In one example, the method of the first aspect may further include, for example, removing the protective layer, and forming lines in the hard mask layer using the filler material lines as mandrels. In one example, removing the protective layer and forming lines in the hard mask layer may be, for example, performed together in a same process.

In one example, the method may further include, for example, removing the filler material lines.

In one example, the starting semiconductor structure is situated over a bulk semiconductor substrate, the method further including patterning the bulk semiconductor substrate using the lines in the hard mask layer as mandrels, the patterning forming semiconductor features (e.g., fins, gates, metal line spaces when used at the BEOL).

In one example, the starting semiconductor structure in the method of the first aspect may be, for example, situated over a bulk semiconductor substrate.

In one example, the filler material in the method of the first aspect may include, for example, one of amorphous silicon and polysilicon.

In a second aspect, disclosed above is a semiconductor structure. The semiconductor structure includes a FinFET in fabrication, the FinFET including a semiconductor substrate, a first layer of filler material above the semiconductor substrate, a hard mask layer over the first layer of filler material and filler material lines over the layer of silicon nitride, and at least one of the filler material lines being surrounded by a layer of oxide. The semiconductor structure may be used with, for example, static random access memory.

In one example, at least one other of the filler material lines may be, for example, surrounded by a layer of protective material. In one example, the layer of protective material may include, for example, a bottom anti-reflective coating.

In one example, the hard mask layer of the semiconductor structure of the second aspect may include, for example, silicon nitride, silicon oxide, silicon oxy nitride (SiON) and silicon oxy carbide (SiOC).

In one example, the filler material of the semiconductor structure of the second aspect may include, for example, one of amorphous silicon and polysilicon.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a starting semiconductor structure, the starting semiconductor structure comprising a filler material layer, a hard mask layer over the filler material layer, and a plurality of filler material lines over the hard mask layer;
forming a protective layer over one or more, but less than all of the plurality of filler material lines, wherein at least one protected filler material line and at least one unprotected filler material line have a same width;
after forming the protective layer, oxidizing unprotected filler material lines, wherein the oxidized at least one unprotected filler material line has a larger width than the at least one protected filler material line; and
after the oxidizing, forming dummy gate mandrels of different width from the hard mask layer using the plurality of filler material lines.

2. The method of claim 1, wherein forming the protective layer comprises:
forming a blanket protective layer over the starting semiconductor structure; and
removing one or more portions of the blanket protective layer, exposing filler material lines to be unprotected.

3. The method of claim 2, wherein the blanket protective layer comprises a bottom anti-reflective coating material.

4. The method of claim 1, further comprising:
removing the protective layer; and
forming a plurality of lines in the hard mask layer using the plurality of filler material lines as mandrels.

5. The method of claim 4, wherein removing the protective layer and forming lines in the hard mask layer are performed together in a same process.

6. The method of claim 4, further comprising removing the plurality of filler material lines.

7. The method of claim 6, wherein the starting semiconductor structure is situated over a bulk semiconductor substrate, the method further comprising patterning the bulk semiconductor substrate using the plurality of lines in the hard mask layer as mandrels, the patterning forming a plurality of semiconductor features.

8. The method of claim 1, wherein the starting semiconductor structure is situated over a bulk semiconductor substrate.

9. The method of claim 1, wherein the filler material comprises one of amorphous silicon and polysilicon.

10-14. (canceled)
